(19) United States
(12) Patent Application Publication
(10) Pub. No.: US 2013/0048604 A1
(43) Pub. Date: Feb. 28, 2013

(54) PHOTORESIST COMPOSITION AND METHOD OF FORMING A FINE PATTERN USING THE SAME

(71) Applicants: Min Kang, Seoul (KR); Jin-Ho Ju, Seoul (KR); Jong-Kwang Lee, Dong-gu (KR); Bong-Yeon Kim, Seoul (KR); Jeong-Won Kim, Suwon-si (KR); Deok-Man Kang, Seongnam-si (KR); Jung-Hwan Cho, Cheonan-si (KR); Kyung-Mi Choi, Cheonan-si (KR)

(72) Inventors: Min Kang, Seoul (KR); Jin-Ho Ju, Seoul (KR); Jong-Kwang Lee, Dong-gu (KR); Bong-Yeon Kim, Seoul (KR); Jeong-Won Kim, Suwon-si (KR); Deok-Man Kang, Seongnam-si (KR); Jung-Hwan Cho, Cheonan-si (KR); Kyung-Mi Choi, Cheonan-si (KR)

(21) Appl. No.: 13/568,233

(22) Filed: Aug. 7, 2012

(30) Foreign Application Priority Data
Aug. 29, 2011 (KR) 10-2011-0086409

(51) Int. Cl. G03F 7/004; B44C 1/22; G03F 7/022; G03F 7/027; G03F 7/016

(52) U.S. Cl. 216/49; 430/270.1; 430/281.1

(57) ABSTRACT

A photoresist composition includes from about 20% to about 50% by weight of a polymer, from about 0.5% to about 1.5% by weight of a photo-acid generator, from about 0.01% to about 0.5% by weight of a photo absorber and the remainder includes an organic solvent. Also provided is a method of forming a fine pattern including forming a thin film on a substrate; forming a photoresist pattern by using a photoresist composition that includes from about 20% to about 50% by weight of a polymer, from about 0.5% to about 1.5% by weight of a photo-acid generator, from about 0.01% to about 0.5% by weight of a photo absorber and a remainder comprising an organic solvent; and patterning the thin film by using the photoresist pattern as an etch-stop layer to form a fine pattern.

### RELATED APPLICATIONS

This application claims priority under 35 U.S.C. §119 to Korean Patent Application No. 10-2011-0086409, filed on Aug. 29, 2011 in the Korean Intellectual Property Office (KIPO), the contents of which are herein incorporated by reference in their entirety.

### TECHNICAL FIELD

The present invention relates to photoresist compositions and methods of forming a fine pattern using the photoresist composition. More particularly, example embodiments of the present invention relate to photoresist compositions, that may be used in the manufacturing of liquid crystal display devices, and methods of forming a fine pattern using the photoresist composition.

### DESCRIPTION OF THE RELATED ART

Generally, elements of a display device are formed through a photolithography process by patterning a thin film. The photolithography process includes forming a photoresist layer on a thin film, exposing the photoresist layer to light, developing the photoresist layer to form a photoresist pattern, and etching the thin film by using the photoresist pattern as an etch-stop layer.

Recently, various methods for forming a fine pattern by using a photolithography process have been developed as desire for a fine pattern increases. When conventional photoresist compositions and conventional exposing devices are used for forming a fine pattern, an additional process is required, and the manufacturing reliability may be negatively affected.

### SUMMARY

Example embodiments of the present invention provide photoresist compositions capable of improving reliability of a fine pattern and a method of forming a fine pattern using the above-mentioned photoresist compositions.

According to an embodiment of the present invention, the photoresist composition includes from about 20% to about 50% by weight of a polymer, from about 0.5% to about 1.5% by weight of a photo-acid generator, from about 0.01% to about 0.5% by weight of a photo absorber and the remainder of an organic solvent.

In an example embodiment, the photoresist composition forms a photoresist layer having a light-exposed portion that is soluble in an alkali developing solution, and a non-exposed portion that is not soluble in the alkali developing solution.

In an example embodiment, the photo absorber may absorb light having a wavelength of from about 100 nm to about 450 nm.

In an example embodiment, the photo absorber may include a hydroxyphenyl benzotriazole-based compound, a hydroxyphenyl triazine-based compound, a hindered amine light stabilizer-based compound or a red shift-based compound. These can be used each alone or in any combination thereof.

In an example embodiment, the photo absorber may include any one of Ciba™ Tinuvin®-928, Tinuvin®-328, Tinuvin®-109, Tinuvin®-384-2, Tinuvin®-405, Tinuvin®-400, Tinuvin®-292HP, Tinuvin®-123 and Tinuvin®-477. These can be used each alone or in a combination thereof.

In an example embodiment, the polymer may have a main chain that is alkali-soluble. For example, the polymer may include a novolac-based resin having ethyl vinyl ether blocking a hydroxyl group of the novolac resin. Alternatively, the polymer may include a styrene-based resin having tert-butylacetate blocking a monomer of polyhydroxystyrene.

In an example embodiment, the photo-acid generator may include any one of a diazonium salt, an ammonium salt, an iodonium salt such as diphenyliodonium triflate, a sulfonium salt such as triphenylsulfonium triflate, a phosphonium salt, an arsonium salt, an oxonium salt, a halogenated organic compound, a quinonediazide compound, a bis(sulfonyl)diazomethane compound, a sulfonic compound, an ester of organic acid compound, an amide of organic acid compound, and an imide of organic acid compound. These can be used each alone or in a combination thereof.

In an example embodiment, the organic solvent may include one or more glycols selected from glycol ether, ethylene glycol alkyl ether acetate, and diethylene glycol.

According to an example embodiment of the present invention, a method of forming a fine pattern is provided. According to the method, a thin film is formed on a substrate. A photoresist pattern is formed on the substrate having the thin film by using a photoresist composition that includes from about 20% to about 50% by weight of a polymer, from about 0.5% to about 1.5% by weight of a photo-acid generator, from about 0.01% to about 0.5% by weight of a photo absorber and the remainder of an organic solvent.

In an example embodiment, the photoresist composition forms a photoresist layer having a light-exposed portion that is soluble in an alkali developing solution, and a non-exposed portion that is not soluble in the alkali developing solution.

In an example embodiment, the photoresist composition is coated to form a photoresist layer, and the photoresist layer is exposed to a light with heat provided thereto, and the photoresist layer is developed. For example, the photoresist layer may be heated on a heated plate having a temperature of about 90° C. to about 130° C.

In an example embodiment, a light-exposed portion of the photoresist layer may be removed by the developing solution.

In an example embodiment, the substrate may include a switching element, and the fine pattern may be a pixel electrode contacting the switching element and including a plurality of micro electrodes having a width of from about 1 μm to about 5 μm.

In an example embodiment, the fine pattern may include a plurality of lattice patterns having a width of about from 1 μm to about 5 μm.

In an example embodiment, the fine pattern may include a plurality of patterns, and the distance between adjacent patterns increases as the distance increases from a predetermined position in one direction.

According to an embodiment of the present invention, the photoresist composition includes a photo absorber added to a polymer and a photo-acid generator. Thus, even if light diffracts between light-blocking portions of a mask so that the photoresist layer under the light-blocking portions receives scattered light, the photo absorber absorbs this scattered light. Thus, activation of the photo-acid generator in a non-exposed portion of the photoresist layer may be prevented. Therefore, the light-exposing margin of the photoresist layer may be improved.

Furthermore, a dissolution contrast, which is the solubility difference between a light-exposed portion and a non-exposed portion of a photoresist layer formed from the photoresist composition, may be increased.

As recited above, the photoresist composition according to an example embodiment of the present invention has improved characteristics. Thus, when the photoresist composition is used for forming a fine pattern, the reliability and stability of the fine pattern may be improved.

### BRIEF DESCRIPTION OF THE DRAWINGS

The above and other features of the present invention will become more apparent from the detailed example embodiments thereof described herein with reference to the accompanying drawings, in which:

FIG. 1A is a cross-sectional view illustrating a light-exposing process in a method of forming a fine pattern according to an example embodiment of the present invention.

FIG. 1B is an enlarged view illustrating region ‘A’ of FIG. 1A.

FIG. 2A is a cross-sectional view illustrating a developing process performed after the light-exposing process illustrated in FIG. 1A.

FIG. 2B is a cross-sectional view illustrating an etching process performed after the developing process illustrated in FIG. 2A.

FIG. 3 is a cross-sectional view illustrating a display device manufactured according to an example embodiment of the present invention.

FIGS. 4A to 4C are cross-sectional views illustrating processes for manufacturing the first display substrate illustrated in FIG. 3.

FIG. 5 is a cross-sectional view illustrating a display device manufactured according to an example embodiment of the present invention.

FIG. 6 is a perspective view illustrating a first polarizing layer illustrated in FIG. 5.

FIG. 7 is a cross-sectional view illustrating a method of forming the first polarizing layer illustrated in FIG. 5.

FIG. 8 is a cross-sectional view illustrating a display device manufactured according to an example embodiment of the present invention.

FIG. 9 is a plan view illustrating a light path converting layer of FIG. 8.

FIG. 10 is a graph showing the refractive index distribution between I and I′ of FIG. 9.

FIG. 11 is a cross-sectional view illustrating a process for forming the light path converting layer illustrated in FIG. 8.

### DETAILED DESCRIPTION

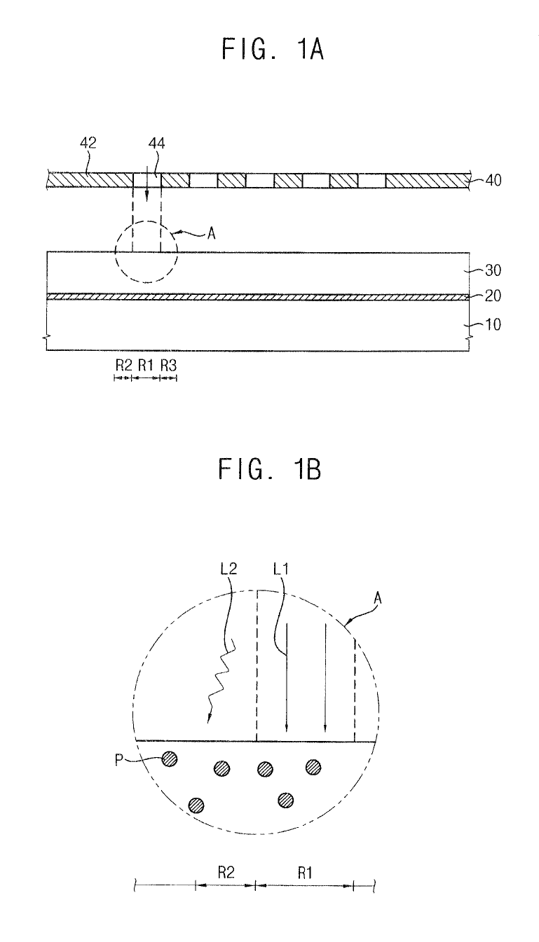

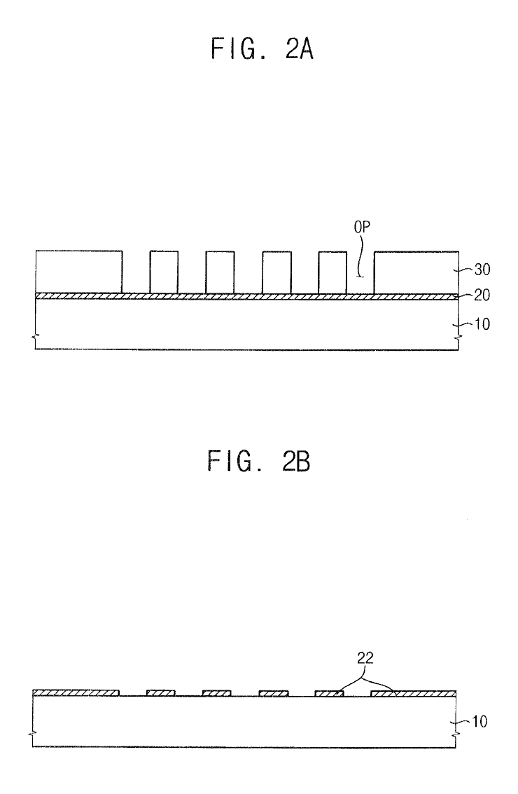

Hereinafter, a photoresist composition according to an example embodiment of the present invention is described. Thereafter, a method of forming a fine pattern using the photoresist composition is described with reference to FIGS. 1A, 1B, 2A and 2B.

A photoresist composition according to an example embodiment of the present invention includes from about 20% to about 50% by weight of a polymer, from about 0.5% to about 1.5% by weight of a photo-acid generator, from about 0.01% to about 0.5% by weight of a photo absorber and the remainder comprising an organic solvent. The photoresist composition may be a positive type photoresist composition, wherein a light-exposed portion of a photoresist layer formed from the photoresist composition has been removed, and a non-exposed portion of the photoresist layer remains.

A) Polymer

The polymer of the photoresist composition may have a main chain that is alkali-soluble, and may optionally have a functional group combined with the main chain. When the photo-acid generator is activated by light, the functional group is separated from the main chain. The polymer having the functional group has a low solubility in an alkali developing solution. However, when the functional group is separated from the main chain, the main chain is reduced to become soluble in the alkali developing solution.

For example, a photo-generated hydrogen ion easily reduces the main chain, which is separated from the functional group, with heat. For example, the main chain may be reduced at a temperature of from about 90° C. to about 130° C. When the heat is added to the reaction between the polymer and the hydrogen ion, the polymer is easily reduced, and the hydrogen ion generated by the reduction of the polymer causes another reduction reaction. Thus, the reduction of the main chain proceeds consecutively and explosively.

When the content of the polymer is less than about 20% by weight based on the total weight of the photoresist composition, the non-exposed portion of the photoresist layer formed from the photoresist composition may be removed by the alkali developing solution. Thus, the reliability the profile of the photoresist pattern may be reduced, and it may be difficult to form a thin layer having a uniform thickness. Also, when the content of the polymer is more than about 50% by weight based on the total weight of the photoresist composition, the amount of the photo-acid generator needs to be increased to effectively reduce the polymer thereby deteriorating the characteristics of the photoresist composition. Furthermore, the content of the organic solvent is relatively reduced so that the photoresist composition may not be uniformly coated on the substrate. Thus, in one embodiment, the content of the polymer is from about 20% to about 50% by weight based on the total weight of the photoresist composition.

Examples of the polymer according to the present invention may include a novolac-based resin or a styrene-based resin, or a combination thereof

The novolac-based resin may have an ethyl vinyl ether group blocking a hydroxyl group, which is an end group of the novolac resin. The novolac resin can be the main chain of the polymer, and the ethyl vinyl ether may correspond to the functional group combined with the main chain to inhibit dissolution of the polymer in the alkali developing solution. For example, the novolac resin can be formed by a condensation reaction of a cresol monomer, and a hydroxyl group of the novolac resin can be blocked by an ethyl vinyl ether to obtain the novolac-based resin.

The styrene-based resin may include a tert-butylacetate group blocking a monomer of polyhydroxystyrene. The main chain of the styrene-based resin may include a styrene monomer and an acetate monomer, and the blocking group blocking a functional group of the styrene-based resin may be tert-butylacetate.

A polystyrene-converted weight average molecular weight of the polymer, which is measured by gel permeation chromatography (GPC), may be from about 1,000 to about 10,000 daltons. When the weight average molecular weight of the polymer is less than about 1,000 daltons, the non-exposed portion of a photoresist layer formed from the photoresist composition may be removed by an alkali developing solution. Furthermore, when the weight average molecular weight of the polymer is more than about 10,000 daltons, the dissolution contrast, which is a solubility difference between a light-exposed portion and a non-exposed portion of a photoresist layer formed from the photoresist composition, is small so that it is hard to form a clear and reliable photo pattern. In an embodiment the weight average molecular weight of the polymer may be from about 3,000 to about 9,000 daltons.

B) Photo-Acid Generator

The photo-acid generator is activated by light to generate a hydrogen ion as an acid. The hydrogen ion generated by the photo-acid generator reduces the polymer. Thus, the reduced polymer is dissolved in the alkali developing solution to be removed from the substrate.

When a content of the photo-acid generator is less than about 0.5% by weight based on the total weight of the photoresist composition, the amount of an acid generated by the photo-acid generator is limiting so that the production of the reduced polymer in the light-exposed region is decreased. Consequently, the light-exposed portion is not easily dissolved by the alkali developing solution so that it is hard to form a clear and reliable photo pattern. When the content of the photo-acid generator is more than about 1.5% by weight based on the total weight of the photoresist composition, the reduction reaction is excessive. lin this case, the photo pattern may be partially damaged thereby causing profile deformation of the photo pattern. For example, the damaged photo pattern may have a round edge.

Examples of the photo-acid generator useful for inclusion in an embodiment of the photoresist compositions of the present invention include a diazonium salt, an ammonium salt, an iodonium salt such as diphenyliodonium triflate, a sulfonium salt such as triphenylsulfonium triflate, a phosphonium salt, an arsonium salt, an oxonium salt and the like. These can be used each alone or in any combination thereof.

The photo-acid generator may further include other materials generating a Bronsted acid or a Lewis acid. For example, the photo-acid generator may further include an halogenated organic compound, a quinonediazide compound, a bis(sulfonyl)diazomethane compound, a sulfonic compound, an ester of organic acid compound, an amide of organic acid compound, an imide of organic acid compound and the like. These can each be used alone or in any combination thereof.

C) Photo Absorber

In an embodiment, the photo absorber absorbs light generated by a light-exposing device for exposing a photoresist layer formed from the photoresist composition to light. For example, the photo absorber may absorb light having a wavelength of from about 100 nm to about 450 nm. Thus, even though leaked light is provided to the portion of the photoresist layer that is intended to be non-exposed, the photo absorber absorbs the leaked light so that activation of the photo-acid generator in the non-exposed portion is prevented.

When the content of the photo absorber is less than about 0.01% by weight based on the total weight of the photoresist composition, the photo absorber is not sufficient to prevent activation of the photo-acid generator in the non-exposed portion. When the content of the photo absorber is more than about 0.5% by weight based on the total weight of the photoresist composition, the amount of light required for activation in the light-exposed portion of the photoresist layer is excessively increased. For this reason, the light-exposing time may be increased, or the required light energy may be increased. Thus, in an embodiment of the present invention, the content of the photo absorber may be from about 0.01% to about 0.5% by weight, or from about 0.01% to about 0.2% by weight so that a light-exposing margin may be improved without changing the light-exposing time and the light energy.

Examples of the photo absorber may include a hydroxyphenyl benzotriazole-based compound, a hydroxyphenyl triazine-based compound, a hindered amine light stabilizer-based compound, a red shift-based compound and the like.

Examples of the hydroxyphenyl benzotriazole-based compound may include Tinuvin®-928 (trade name, Ciba™, U.S.A.), Tinuvin®-328, Tinuvin®-109, Tinuvin®-384-2 and the like. Examples of the hydroxyphenyl triazine based compound may include Tinuvin®-405, Tinuvin®-400 and the like. Examples of the hindered amine light stabilizer-based compound may include Tinuvin®-292HP, Tinuvin®-123 and the like. Examples of the red shift-based compound include Tinuvin®-477 and the like.

D) Organic Solvent

In an embodiment of the present invention, the organic solvent corresponds to the remainder of the photoresist composition, excluding the polymer, the photo-acid generator and the photo absorber. Thus, summation of contents of the organic solvent, the photoresist composition excluding the polymer, the photo-acid generator and the photo absorber is about 100% by weight.

Examples of the organic solvent of an embodiment of the present invention include alcohols such as for example, methanol and ethanol, ethers such as tetrahydrofurane, glycol ethers such as ethylene glycol monomethyl ether and ethylene glycol monoethyl ether, ethylene glycol alkyl ether acetates such as methyl cellosolve acetate and ethyl cellosolve acetate, diethylene glycols such as diethylene glycol monomethyl ether, diethylene glycol monoethyl ether and diethylene glycol dimethyl ether, propylene glycol monoalkyl ethers such as propylene glycol methyl ether, propylene glycol ethyl ether, propylene glycol propyl ether and propylene glycol butyl ether, propylene glycol alkyl ether acetates such as propylene glycol methyl ether acetate, propylene glycol ethyl ether acetate, propylene glycol propyl ether acetate and propylene glycol butyl ether acetate, propylene glycol alkyl ether propionates such as propylene glycol methyl ether propionate, propylene glycol ethyl ether propionate, propylene glycol propyl ether propionate and propylene glycol butyl ether propionate, aromatic compounds such as toluene and xylene, ketones such as methyl ethyl ketone, cyclohexanone and 4-hydroxy-4-methyl-2-pentanone, and ester compounds such as methyl acetate, ethyl acetate, propyl acetate, butyl acetate, ethyl 2-hydroxypropionate, methyl 2-hydroxy-2-methyl propionate, ethyl 2-hydroxy-2-methyl propionate, methyl hydroxyacetate, ethyl hydroxyacetate, butyl hydroxyacetate, methyl lactate, ethyl lactate, propyl lactate sulfate, butyl lactate, methyl 3-hydroxypropionate, ethyl 3-hydroxypropionate, propyl 3-hydroxypropionate, butyl 3-hydroxypropionate, methyl 2-hydroxy-3-methyl butanoate, methyl methoxy acetate, ethyl methoxy acetate, propyl methoxy acetate, butyl methoxy acetate, methyl ethoxy acetate, ethyl ethoxy acetate, propyl ethoxy acetate, butyl ethoxy acetate, methyl propoxy acetate, ethyl propoxy acetate, propyl propoxy acetate, butyl propoxy acetate, methyl butoxy acetate, ethyl butoxy acetate, propyl butoxy acetate, butyl butoxy acetate, methyl 2-methoxypropionate, ethyl 2-methoxypropionate, propyl 2-methoxypropionate, butyl 2-methoxypropionate, methyl 2-ethoxypropionate, ethyl 2-ethoxypropionate, propyl 2-ethoxypropionate, butyl 2-ethoxypropionate, methyl 2-butoxypropionate, ethyl 2-butoxypropionate, propyl 2-butoxypropionate, butyl 2-butoxypropionate, methyl 3-methoxypropionate, ethyl 3-methoxypropionate, propyl 3-methoxypropionate, butyl 3-methoxypropionate, methyl 3-ethoxypropionate, ethyl 3-ethoxypropionate, propyl 3-ethoxypropionate, butyl 3-ethoxypropionate, methyl 3-propoxypropionate, ethyl 3-propoxypropionate, propyl 3-propoxypropionate, butyl 3-propoxypropionate, methyl 3-butoxypropionate, ethyl 3-butoxypropionate, propyl 3-butoxypropionate, butyl 3-butoxypropionate, etc. Among the above examples, glycol ethers, ethylene glycol alkyl ether acetates and diethylene glycols can be used in view of the solubility and reactivity of each of the components composing the photoresist composition and the manufacturing condition of the coating layer.

Preparing a Photoresist Coposition

### EXAMPLE 1

A cresol monomer including m-cresol and p-cresol in a weight ratio of about 60:40 was reacted with formaldehyde through condensation reaction in the presence of oxalic acid as a catalyst to obtain a cresol-novolac resin having a weight average molecular weight of about 6,000 daltons. Thereafter, about 50% of the hydroxyl groups of the cresol-novolac resin were blocked by ethylvinylether by yielding a novolac-based resin.

A solid content including the novolac-based resin, a sulfonic compound as a photo-acid generator and Tinuvin®-328 as a photo absorber was mixed with propylene glycol monomethyl ether acetate (PGMEA) to prepare the photoresist composition of Example 1 according to an embodiment of the present invention. The photoresist composition included about 30% by weight of the novolac-based resin, about 1% by weight of the sulfonic compound, about 0.1% by weight of Tinuvin®-328 and about 68.9% by weight of PGMEA.

### EXAMPLE 2

A solid content including the novolac-based resin used for Example 1 as specified above, a sulfonic compound as a photo-acid generator and Tinuvin®-405 as a photo absorber was mixed with propylene glycol monomethyl ether acetate (PGMEA) to prepare the photoresist composition of Example 2 according to an embodiment of the present invention. The photoresist composition included about 30% by weight of the novolac-based resin, about 1% by weight of the sulfonic compound, about 0.1% by weight of Tinuvin®-405 and about 68.9% by weight of PGMEA.

### EXAMPLE 3

A solid content including the novolac-based resin used for Example 1, a sulfonic compound as a photo-acid generator and Tinuvin®-292HP as a photo absorber was mixed with propylene glycol monomethyl ether acetate (PGMEA) to prepare the photoresist composition of Example 3 according to an embodiment of the present invention. The photoresist composition included about 30% by weight of the novolac-based resin, about 1% by weight of the sulfonic compound, about 0.1% by weight of Tinuvin®-292HP and about 68.9% by weight of PGMEA.

### EXAMPLE 4

A solid content including the novolac-based resin used for Example 1, a sulfonic compound as a photo-acid generator and Tinuvin®-477 as a photo absorber was mixed with propylene glycol monomethyl ether acetate (PGMEA) to prepare the photoresist composition of Example 4 according to an embodiment of the present invention. The photoresist composition included about 30% by weight of the novolac-based resin, about 1% by weight of the sulfonic compound, about 0.1% by weight of Tinuvin®-477 and about 68.9% by weight of PGMEA.

### EXAMPLE 5

A solid content including the novolac-based resin used for Example 1, a sulfonic compound as a photo-acid generator and Tinuvin®-477 as a photo absorber was mixed with propylene glycol monomethyl ether acetate (PGMEA) to prepare the photoresist composition of Example 5 according to an embodiment of the present invention. The photoresist composition included about 30% by weight of the novolac-based resin, about 1% by weight of the sulfonic compound, about 0.01% by weight of Tinuvin®-477 and about 68.99% by weight of PGMEA.

### EXAMPLE 6

The photoresist composition of Example 6 according to an embodiment of the present invention was prepared by a similar method to that used to prepare the photoresist composition of Example 5 except that the photoresist composition of Example 6 included about 0.05% by weight of Tinuvin®-477 as a photo absorber and about 68.95% by weight of PGMEA.

### EXAMPLE 7

The photoresist composition of Example 7 according to an embodiment of the present invention was prepared by a similar method as the photoresist composition of Example 5 except that the photoresist composition of Example 7 included about 0.15% by weight of Tinuvin®-477 as a photo absorber and about 68.85% by weight of PGMEA.

### EXAMPLE 8

The photoresist composition of Example 8 accordin gto an embodiment of the present invention was prepared by a similar method to that used to prepare the photoresist composition of Example 1 except that the photoresist composition of Example 8 included about 0.2% by weight of Tinuvin®-328 as a photo absorber and about 68.8% by weight of PGMEA.

### EXAMPLE 9

The photoresist composition of Example 9 accordin gto an embodiment of the present invention was prepared by a similar method to that used to prepare the photoresist composition of Example 5 except that the photoresist composition of Example 9 included about 0.3% by weight of Tinuvin®-477 as a photo absorber and about 68.7% by weight of PGMEA.

### EXAMPLE 10

The photoresist composition of Example 10 according to an embodiment of the present invention was prepared by a similar method to that used to prepare the photoresist composition of Example 5 except that the photoresist composition of Example 10 included about 0.5% by weight of Tinuvin®-477 as a photo absorber and about 68.5% by weight of PGMEA.

### COMPARATIVE EXAMPLE 1

The solid content including the novolac-based resin used for Example 1 and a sulfonic compound as a photo-acid generator was mixed with propylene glycol monomethyl ether acetate (PGMEA) to prepare the photoresist composition of Comparative Example 1. The photoresist composition included about 30% by weight of the novolac-based resin, about 1% by weight of the sulfonic compound and about 69% by weight of PGMEA.

### COMPARATIVE EXAMPLE 2

The solid content including the novolac-based resin used for Example 1, a sulfonic compound as a photo-acid generator and Tinuvin®-477 as a photo absorber was mixed with propylene glycol monomethyl ether acetate (PGMEA) to prepare the photoresist composition of Comparative Example 2. The photoresist composition included about 30% by weight of the novolac-based resin, about 1% by weight of the sulfonic compound, about 1% by weight of Tinuvin®-477 and about 68% by weight of PGMEA.

### COMPARATIVE EXAMPLE 3

The solid content including the novolac-based resin used for Example 1, a sulfonic compound as a photoacid generator and Tinuvin®-477 as a photo absorber was mixed with propylene glycol monomethyl ether acetate (PGMEA) to prepare the photoresist composition of Comparative Example 2. The photoresist composition included about 30% by weight of the novolac-based resin, about 1% by weight of the sulfonic compound, about 0.8% by weight of Tinuvin®-477 and about 68.2% by weight of PGMEA.

Evaluation 1 for Photoresist Composition

Photoresist compositions of Examples 1 to 5 and Comparative Examples 1 and 2 were each individually spin-coated on a substrate having a thin film including indium zinc oxide to form photoresist layers, and the photoresist layers were exposed to light by a Nikon FX-601 (NA-0.1, trade name, Nikon, Japan). Thereafter, the photoresist layers were baked and developed by trimethylphenyl ammonium hydroxyl aqueous solution of 2.38% by weight. Thereafter, a photo-sensitivity and a pattern profile of the photoresist layers were examined. The results obtained are shown in Table 1 below.

TABLE 1

| | Light-exposing margin | Photo-sensitivity | Pattern profile |
|---|---|---|---|
| Example 1 | ◯ | ◯ | ◯ |
| Example 2 | ◯ | ◯ | ◯ |
| Example 3 | ◯ | ◯ | ◯ |
| Example 4 | ⊚ | ◯ | ◯ |
| Example 5 | Δ | ◯ | Δ |
| Comparative | X | ◯ | Δ |
| Example 1 | | | |
| Comparative | ⊚ | Δ | ◯ |
| Example 2 | | | |

In Table 1 shows the evaluation of the sharpness in definition of the light-exposed margin wherein “\textcircled{O}” represents “very good”, and “O” represents “good”, and “Δ” represents “medium”, and “X” represents “poor”. In the evaluation of the photo-sensitivity and the pattern profile, “O” represents “good”, and “Δ” represents “medium”.

Referring to Table 1, the photoresist compositions of Examples 1 to 5 have superior light-exposed margins when compared to the photoresist composition of Comparative Example 1, which does not include the photo absorber. Thus, it can be seen that the photoresist compositions of Examples 1 to 5, that included the photo absorber absorbed the scattered light provided to the non-exposed portion of the photoresist layers so that the sharpness and definition of the light-exposed margin was improved.

The photoresist composition of Comparative Example 2 has a good light-exposed margin. However, since the photoresist composition of Comparative Example 2 includes a larger amount of the photo absorber as compared to the photoresist compositions of Examples 1 and 2, the photoresist composition of Comparative Example 2 has a low photo-sensitivity. Thus, it can he noted that the photoresist layer formed from the photoresist composition of Comparative Example 2 requires more light amount or a longer light-exposure time, which may reduce manufacturing productivity for components that include such compositions.

Furthermore, pattern profiles of the photoresist layers formed from the photoresist compositions of Examples 1 to 5 are not deteriorated or damaged as compared to the pattern profile of the photoresist layer formed from the photoresist composition of Comparative Example 1. Thus, it can be noted that using the photo absorber does not deteriorate the stability profile of the photoresist pattern.

Evaluation 2 for Photoresist Composition

Photoresist compositions of Examples 4 to 10 and Comparative Examples 1 and 3 were each individually spin-coated on a substrate having a thin film including indium zinc oxide to form photoresist layers, and the photoresist layers were exposed to light by a Nikon FX-601 (NA=0.1, Nikon, Japan). Thereafter, the photoresist layers were baked and developed by trimethylphenyl ammonium hydroxyl aqueous solution of 2.38% by weight. Thereafter, the light energy required for removing the photoresist layer to expose the thin film was measured. The results obtained are shown in Table 2.

TABLE 2

| | Light energy (mJ/cm²) |
|---|---|
| Example 4 | 150 |
| Example 5 | 88 |
| Example 6 | 100 |
| Example 7 | 216 |
| Example 8 | 250 |
| Example 9 | 300 |
| Example 10 | 330 |
| Comparative Example 1 | 80 |
| Comparative Example 3 | 350 |

Referring to Table 2, it can be seen that the light energy required for removing the photoresist layer to expose the thin film increased as the content of the photo absorber increased. The photoresist compositions of Examples 4 to 10 need more light energy as compared to the photoresist composition of Comparative Example 1 which does not include the photo absorber. However, the photoresist compositions of Examples 4 to 10 improve the light-exposing margin (data not shown). The photoresist composition of Comparative Example 3 requires much more light energy, which may be greater than capacity of a general light-exposing device, as compared to the photoresist compositions of Examples 4 to 10. Thus, it should be noted that in an embodiment of the present invention, the photoresist composition mayinclude from about 0.01% to about 0.5% by weight of the photo absorber based on the total weight of the photoresist composition.

In an embodiment, the photoresist composition may include from about 0.01% to about 0.2% by weight of the photo absorber based on the total weight of the photoresist composition so that the light-exposing margin may be improved without reducing the photo-sensitivity.

According to certain example embodiments of the present invention, the photoresist composition includes a polymer, a photo-acid generator and a photo absorber. Thus, even though a non-exposed portion of a photoresist layer, which is covered by a light-blocking portion of a mask, receives scattered light, the photo absorber may absorb the scattered light so that activation of the photo-acid generator in the non-exposed portion is prevented. Thus, the light-exposed margin may be improved.

Furthermore, the dissolution contrast of the photoresist layer, which corresponds to the solubility difference with respect to an alkali developing solution between the non-exposed portion and the light-exposed portion, may also be increased.

A method of forming a fine pattern according to an embodiment of the present invention using the previously recited photoresist composition will now be described with reference to accompanying drawings.

FIG. 1A, is a cross-sectional view illustrating a light-exposing process in a method of forming a fine pattern according to an example embodiment of the present invention, and FIG. 1B is an enlarged view illustrating region ‘A’ of FIG. 1A.

Referring to FIG. 1A, a thin film 20 is formed on a base substrate 10, and a photoresist layer 30 is formed on the base substrate 10 having the thin film 20 disposed thereon. The photoresist layer 30 is formed by coating a photoresist composition on the thin film 20. The photoresist composition includes from about 20% to about 50% by weight of a polymer, from about 0.5% to about 1.5% by weight of a photo-acid generator, from about 0.01% to about 0.5% by weight of a photo absorber and some or all of the remainder of an organic solvent. For explanation, the photo absorber is represented by “P” in FIG. 1B. The photoresist composition is substantially the same as the previously described photoresist composition. Therefore, duplicate descriptions will be omitted.

A mask 40 is disposed on the photoresist layer 30, and light is irradiated onto the photoresist layer 30 from a light source disposed on or above the mask 40. The mask 40 includes a light-blocking portion 42 for blocking light, and a light-transmitting portion 44 for transmitting light.

Referring to FIGS. 1A and 1B, light passing through the light-transmitting portion 44 is provided to a light-exposed portion R1 of the photoresist layer 30. The light partially diffracts and partially scatters between the light-transmitting portion 44 and the light-blocking portion 42 so that a portion R2 and R3 of the photoresist layer 30, which is covered by the light-blocking portion 42, is exposed to scattered light L2. Hereinafter, the light passing through the light-transmitting portion 44 will be referred asstraight light L1 to distinguish it from the scattered light L2.

In an ideal condition, the portions R2 and R3 of the photoresist layer 30, which are covered by the light-blocking portion 42, are not exposed to light. However, since the width of the light-transmitting portion 44, which is the distance between adjacent light-blocking portions, is small, the straight light L1 may be diffracted and scattered. In an embodiment of the present invention the distance between adjacent light-blocking portions may be from about 1 μm to about 5 μm.

Since the photo absorber P of the light-exposed portion R1 absorbs a portion of the straight light L1, the light energy required for reducing the polymer sufficiently in the light-exposed portion R1 may be greater than the light energy required for reaction of the photoresist layer formed from a conventional photoresist composition. For example, when the light energy required for reaction of the photoresist layer formed from the photoresist composition of Comparative Example 1 is taken as 1, the light energy required for reduction of the polymer sufficiently in the light-exposed portion R1 may be greater than 1. To avoid the increase in the light energy required to sufficiently reduce the polymer of the photoresist layer including the photo absorber P, the concentration of the developing solution may be increased, or the thickness of the photoresist layer may be decreased.

If the photoresist composition does not include the photo absorber P, the photo-acid generator may be activated in the portion R2 and R3 of the photoresist layer 30, which is exposed to the scattering light L2, to reduce the polymer in the portion R2 and R3 of the photoresist layer 30. This may cause the portion R2 and R3 of the photoresist layer 30 to be damaged by the developing solution. However, the photoresist composition according to an example embodiment of the present invention includes the photo absorber for absorbing the scattering light L2. Thus, damage to the portion R2 and R3 of the photoresist layer 30 may be prevented. Therefore, the straight light L1 is substantially provided only to the light-exposed portion R1 so that a light-exposed margin of the photoresist layer 30 is improved.

The photo-acid generator is not activated in the non-exposed portion, which is covered by the light-blocking portion 42, so that the polymer in the non-exposed portion is not dissolved by the developing solution, and the photo-acid generator is activated only in the light-exposed portion R1 so that the polymer in the light-exposed portion R1 becomes easily soluble in the developing solution.

The light-exposing process may be performed on a plate so that the base substrate 10 having the photoresist layer 30 is heated at a predetermined temperature. The heating process provides heat energy to the photoresist layer 30 in addition to the light energy of the straight light L1. The temperature of the plate may be from about 90° C. to about 130° C. In an embodiment of the present invention, the temperature of the plate is about 110° C. The heat energy accelerates the reduction reaction of the polymer due to acid generated by the photo-acid generator. The temperature of the plate may be lower than the temperature in the general process for manufacturing a display substrate.

FIG. 2A is a cross-sectional view illustrating a developing process performed after the light-exposing process illustrated in FIG. 1A.

Referring to FIG. 2A, after exposure to light, the photoresist layer 30 is developed to remove the photoresist layer 30 corresponding to the light-transmitting portion 44 so that a plurality of holes OP are formed. The photoresist layer 30 having the holes OP is defined as a photoresist pattern.

In an embodiment of the invention, the light-exposed portion, R1 corresponding to the light-transmitting portion 44 is removed, and the non-exposed portion remains to form the photoresist pattern. The photoresist layer including the photo absorber P has a high dissolution contrast between the light-exposed portion R1 and the non-exposed portion with respect to the developing solution. Thus, the photoresist pattern may be stably formed.

FIG. 2B is a cross-sectional view illustrating an etching process performed after the developing process illustrated in FIG. 2A.

Referring to FIG. 2B, the thin film 20 is etched by using the photoresist pattern, which is the photoresist layer 30 having the holes OP, as an etch-stop layer. The thin film 20 may be wet-etched or dry-etched. The thin film 20 is patterned to form a fine pattern 22. Thereafter, the photoresist pattern is removed.

The fine pattern 22 may have various shapes depending on the design of the mask 40. Since the distance between adjacent light-blocking portions 42 is from about 1 μm to about 5 μm, the width of the fine pattern 22 or the distance between adjacent fine patterns may be also from about 1 μm to about 5 μm.

As described above, the photoresist pattern according to an embodiment of the present invention is formed by using a photoresist composition including a photo absorber. Thus, the photoresist pattern may be precisely and uniformly formed. By this method, a fine pattern may be easily formed using the photoresist composition as described.

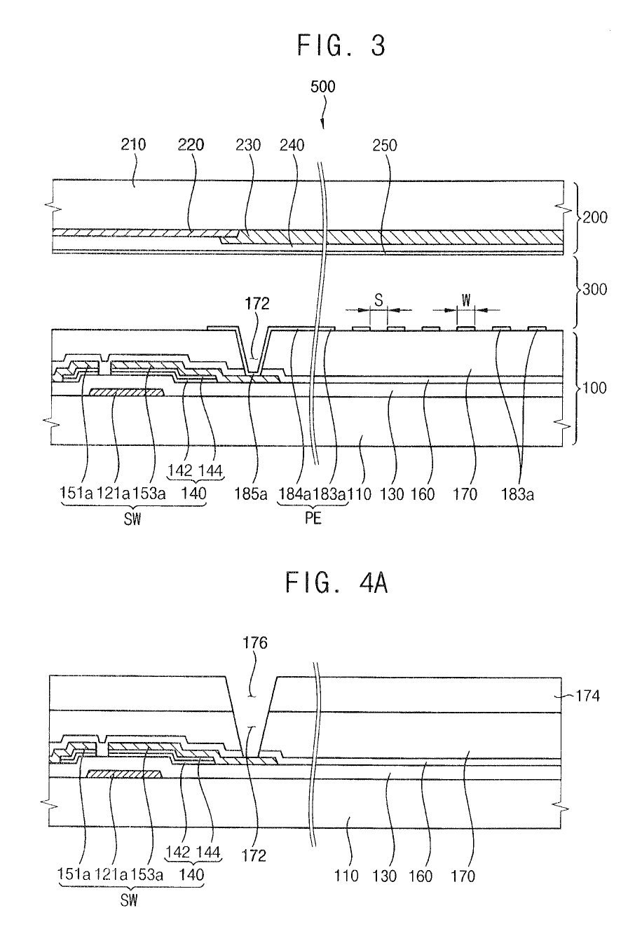

A display device and a method for manufacturing the display device will be explained more fully below with reference to FIGS. 3 to 11.

FIG. 3 is a cross-sectional view illustrating a display device manufactured according to an example embodiment of the present invention.

Referring to FIG. 3, the embodiment exemplified as display device 500 includes a first display substrate 100, a second display substrate 200 and a liquid crystal layer 300. The first and second display substrates 100 and 200 are oriented so that the layers disposed thereon face each other, and the liquid crystal layer 300 is interposed between the first and second display substrates 100 and 200.

In an exemplary embodiment, the first display substrate 100 includes a switching element SW and a pixel electrode PE connected to the switching element SW, which is formed on a first base substrate 110. The switching element SW includes a gate electrode 121a, an active pattern 140, a source electrode 151a and a drain electrode 153a. The active pattern 140 may include a semiconductor layer 142 and an ohmic contact layer 144. The gate electrode 121a is insulated from the active pattern 140 by a first insulating layer 130, and a second insulating layer 160 and a planarizing layer 170 formed to cover the source and drain electrodes 151a and 153a. The pixel electrode PE contacts the drain electrode 153a through a contact hole 172 formed through the second insulating layer 160 and the planarizing layer 170.

The pixel electrode PE includes a plurality of micro electrodes 183a, a contact electrode 185a contacting the drain electrode 153a, and a bridge pattern (not shown) physically and electrically connecting the micro electrodes 183a to the bridge pattern. The micro electrodes 183a may have a radial shape diverging from a body having a cross shape in a plan view. Each of the micro electrodes 183a may have a width W of from about 1 μm to about 5 μm, and the slit width S, which is the distance between adjacent micro electrodes, may be from about 1 μm to about 5 μm.

The second display substrate 200 includes a light-blocking pattern 210, a color filter 230, an overcoated layer 240 and a common electrode 250, which are formed on a second base substrate 210. The common electrode 250 faces the pixel electrode PE, and is formed entirely on a surface of the second base substrate 210.

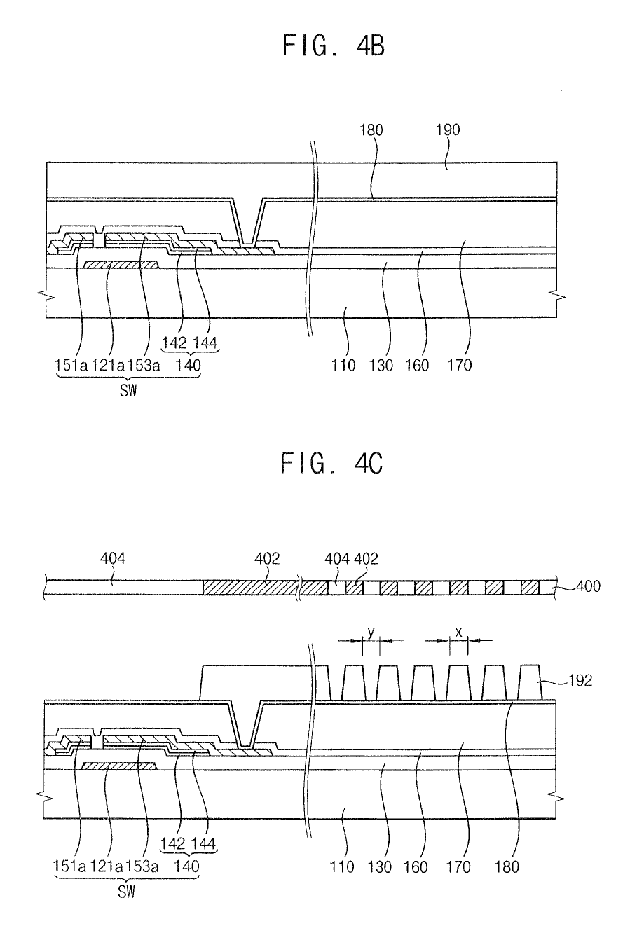

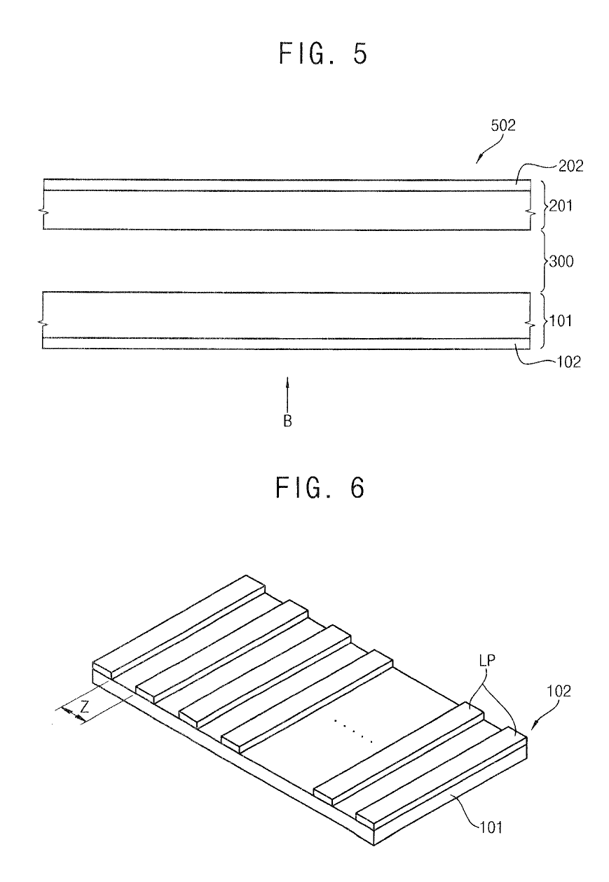

FIGS. 4A to 4C are cross-sectional views illustrating embodiments of the processes for manufacturing the first display substrate illustrated in FIG. 3.

Referring to FIG. 4A, the gate electrode 121a, the first insulating layer 130, the active pattern 140, the source electrode 151a, the drain electrode 153a and the second insulating layer 160 are sequentially formed on the first base substrate 110.

The planarizing layer 170 is formed on the second insulating layer 160. The planarizing layer 170 may be an organic layer which is not photo-sensitive.

A photo pattern 174 is formed on the planarizing layer 170. The photo pattern 174 is formed by coating a photoresist composition on the previously deposited thin film 20 (See FIG. 1). The photoresist composition includes from about 20% to about 50% by weight of a polymer, from about 0.5% to about 1.5% by weight of a photo-acid generator, from about 0.01% to about 0.5% by weight of a photo absorber and the remainder includes an organic solvent. The process for forming the photo pattern 174 is substantially the same as the process for forming a photoresist pattern, which was described above with reference to FIGS. 1A and 2A. Therefore, duplicate descriptions will be omitted.

The photo pattern 174 has an opening 176 disposed on the drain electrode 153a. A width of the opening 176 may be about 1 μm to about 5 μm. The planarizing layer 170 is partially exposed through the photo pattern 174. The planarizing layer 170 and the second insulating layer 160 are etched by using the photo pattern 174 as an etch-stop layer to form the contact hole 172. Since the photo pattern 174 is formed from the photoresist composition including the photo absorber, the contact hole 172 may be accurately and finely formed.

In an embodiment of the present invention, the photo pattern 174 is removed by a stripping solution after the contact hole 172 is formed.

In an embodiment of the invention that is different from that represented in FIG. 4A, when the planarizing layer 170 is a photo-sensitive organic layer, the contact hole 172 may be formed by exposing the planarizing layer 170 to light and developing the planarizing layer 170 without forming the photo pattern 174. The photo-sensitive organic layer may be formed from a conventional positive/negative type photoresist composition.

Referring to FIG. 4B, in an embodiment of the present invention an electrode layer 180 is formed on the planarizing layer 170 having the contact hole 172. The electrode layer 180 may include indium oxide. In particular, the electrode layer 180 may include indium zinc oxide, or indium tin oxide, or the like. The electrode layer 180 is formed entirely on the surface of the first base substrate 110.

A photoresist layer 190 is formed on the first base substrate 110 having the electrode layer 180. The photoresist layer 190 includes from about 20% to about 50% by weight of a polymer, from about 0.5% to about 1.5% by weight of a photo-acid generator, from about 0.01% to about 0.5% by weight of a photo absorber and the remainder includes an organic solvent.

Referring to FIG. 4C, in an embodiment of the present invention a mask 400 is disposed on the first base substrate 110 having the photoresist layer 190, and a light is provided to the photoresist layer 190 from a light source disposed on or above the mask 400. The mask 400 includes a light-blocking portion 402 and a light-transmitting portion 404. The light-transmitting portion 404 may be defined as a slit between adjacent light-blocking portions. The mask 400 is disposed such that the light-blocking portions 404 correspond to the micro electrodes 183a illustrated in FIG. 3. A light-exposing process using the mask 400 for the photoresist layer 190 is substantially the same as the light-exposing process using the mask 40 for the photoresist layer 30, which is explained with reference to FIG. 1A. Therefore, duplicate descriptions will be omitted.

After the photoresist layer 190 is exposed to light, the photoresist layer 190 is developed to form a photo pattern 192. A width X of the photo pattern 192 may be from about 1 μm to about 5 μm, and a distance Y between adjacent photo patterns 192 may be from about 1 μm to about 5 μm. Since the photoresist layer 190 is formed from the photoresist composition including the photo absorber, the photo pattern 192 may have a high resolution and may be formed uniformly. The electrode layer 180 is partially exposed through the photo pattern 192, and is etched by using the photo pattern 192 as an etch-stop layer to form the pixel electrode PE. As a result, the micro electrodes 183a having a width of from about 1 μm to about 5 μm are formed.

The photo pattern 192 is removed by a stripping solution. By this method the first display substrate 100 as illustrated in FIG. 3 is manufactured.

According to the above embodiment, the photoresist composition including the photo absorber is used for forming the contact hole 172 or forming the pixel electrode PE. Thus, the size of the contact hole 172 may be reduced, and the micro electrodes 183a of the pixel electrode PE may be finely and stably formed.

FIG. 5 is a cross-sectional view illustrating a display device manufactured according to an example embodiment of the present invention. FIG. 6 is a perspective view illustrating the first polarizing layer illustrated in FIG. 5.

Referring to FIGS. 5 and 6, the display device 502 according to an embodiment of the present invention includes a first display substrate 101, a first polarizing layer 102, a second display substrate 201, a second polarizing layer 202 and a liquid crystal layer 300. The first and second display substrates 101 and 201 face each other, and the liquid crystal layer 300 is interposed between the first and second display substrates 101 and 201. The first polarizing layer 102 is formed on an outer surface of the first display substrate 101, and the second polarizing layer 202 is formed on an outer surface of the second substrate 201.

The first display substrate 101 is illustrated in FIG. 5, however, the first display substrate 101 may be substantially the same as the first display substrate 100 illustrated in FIG. 3. Furthermore, the second display substrate 201 is illustrated in FIG. 5, however, the second display substrate 201 may be substantially the same as the first display substrate 200 illustrated in FIG. 3. Therefore duplicate descriptions will be omitted.

The first polarizing layer 102 is formed integrally with the first display substrate 101, and the second polarizing layer 202 is formed integrally with the second display substrate 201. For example, lattice patterns LP of the first polarizing layer 102 maybe formed directly on a base substrate of the first display substrate 101. The distance Z between adjacent lattice patterns LP may be from about 1 μm to about 5 μm. The lattice patterns LP extend in a first direction, and are arranged in a second direction crossing the first direction. Light incident on the lattice patterns LP is blocked or reflected, and polarization is generated between the lattice patterns LP. Lattice patterns of the second polarizing layer 202 may be arranged to cross the lattice patterns LP of the first polarizing layer 102 in a plan view to form a predetermined cross angle.

According to a conventional method for manufacturing a display substrate having a polarizing member, a polarizing plate is assembled in a display panel. However, the display device 502 manufactured according to an example embodiment of the present invention includes the first polarizing layer 102 formed integrally with the first display substrate 101, and the second polarizing layer 202 formed integrally with the second display substrate 201. Thus, the thickness of the display device 502 can be reduced, and an assembly process can be simplified.

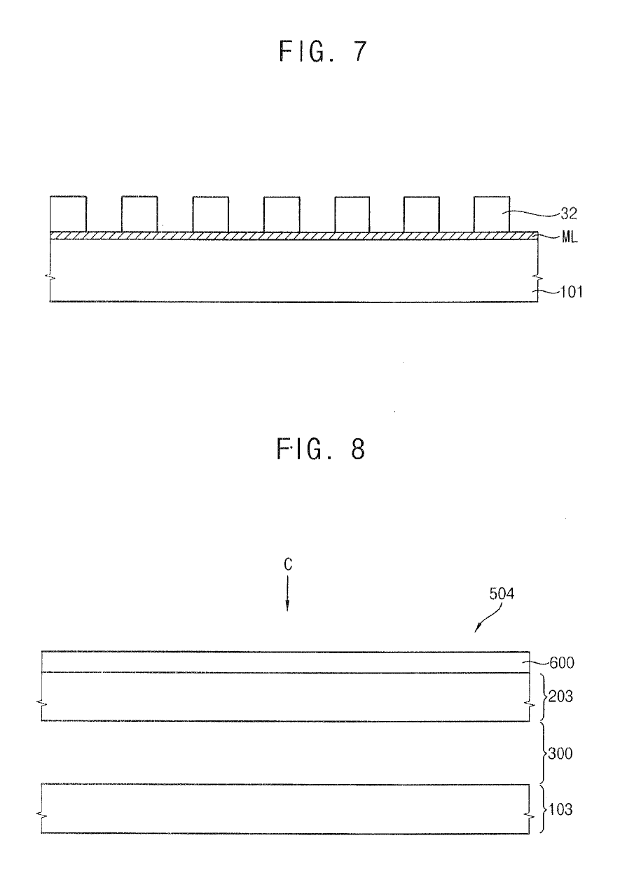

FIG. 7 is a cross-sectional view illustrating a method according to an embodiment of the present invention for forming the first polarizing layer illustrated in FIG. 5.

Referring to FIG. 7, a metal layer ML is formed on the first base substrate of the first display substrate 101, and a photo pattern 32 is formed on the metal layer ML.

The metal layer ML may be formed on the first base substrate before or after the switching element SW illustrated in FIG. 3 is formed on the first base substrate.

The photo pattern 32 is formed from a photoresist composition including from about 20% to about 50% by weight of a polymer, from about 0.5% to about 1.5% by weight of a photo-acid generator, from about 0.01% to about 0.5% by weight of a photo absorber and the remainder including an organic solvent. Since the photoresist composition includes the photo absorber, the photo pattern 32 may be finely and stable formed. Thus, the lattice pattern LP may be finely formed by using the photo pattern 32.

In contrast to FIGS. 5 to 7, the first polarizing layer 102 may be formed between the first base substrate 110 and the gate electrode 121a in the first display substrate 100 illustrated in FIG. 3. A planarzing layer may be further formed between the first polarizing layer 102 and the gate electrode 121a. the position of the second polarizing layer 202 may be determined independently from the first polarizing layer 102. As illustrated in FIG. 5, the second polarizing layer 202 may be disposed on an outer surface of the second display substrate 201, or in contrast to the arrangement shown in FIG. 5, the second polarizing layer 202 may be disposed to face the liquid crystal layer 300.

As described above, the photoresist composition including the photo absorber is used for forming the first polarizing layer 102 on the first display substrate 101 and forming the second polarizing layer 202 on the second display substrate 201. Thus, the lattice pattern LP may be accurately, i.e. finely and stably formed.

FIG. 8 is a cross-sectional view illustrating a display device manufactured according to an example embodiment of the present invention.

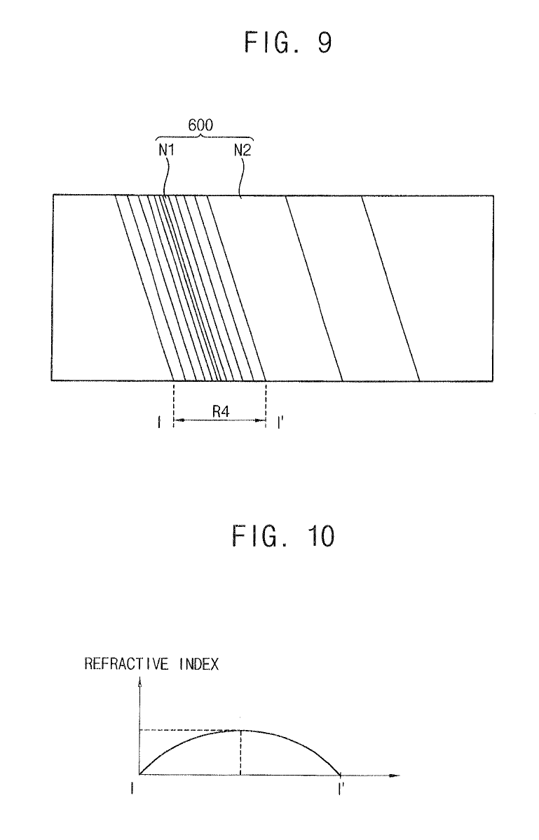

FIG. 9 is a plan view illustrating a light path converting layer of FIG. 8, and FIG. 10 is a graph showing the refractive index distribution across the section I and I′ shown in FIG. 9.

Referring to FIGS. 8, 9 and 10, the display device 504 includes a first display substrate 103, a second display substrate 203, a liquid crystal layer 300 and a light path converting layer 600. The first display substrate 103, the second display substrate 203 and the liquid crystal layer 400 may he substantially the same as the first display substrate 100, the second display substrate 200 and the liquid crystal layer 300, which are described above with reference to FIG. 3. Therefore, duplicate descriptions will be omitted.

The light path converting layer 600 includes a first pattern N1 and a second pattern N2, which are arranged in a direction on the second display substrate 203. The first and second patterns N1 and N2 are repeatedly arranged to entirely cover the surface of the second display substrate 203. A two-dimensional image displayed by the first display substrate 103, the second display substrate 203 and the liquid crystal layer 400 may be converted to a three-dimensional image by the light path converting layer 600.

The first pattern N1 includes a plurality of bar-patterns. A distance between adjacent bar-patterns is greater in peripheral regions I and I′ than in a central region. When the distance between adjacent bar-patterns changes depending on the region, and the refractive index of the light passing through the second display substrate 203 changes. For example, the refractive index of the light passing through the second display substrate 203 is maximized in the central region, and is gradually reduced as it approaches the peripheral regions I and I′. Thus, the first pattern N1 may function as a Fresnel lens. The distance between adjacent bar-patterns may be from about 1 μm to about 5 μm.

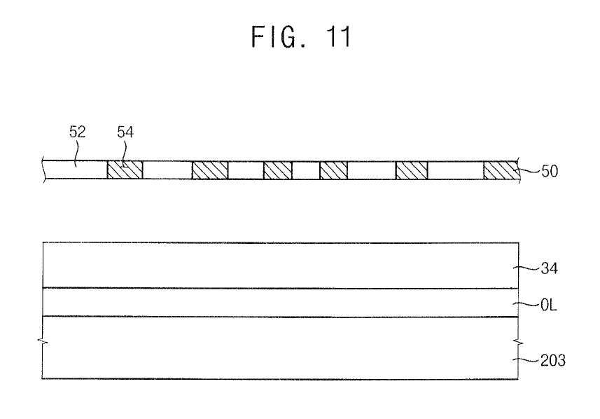

FIG. 11 is a cross-sectional view illustrating a process for forming the light path converting layer illustrated in FIG. 8 according to an embodiment of a method of the present invention.

Referring to FIG. 11, an organic layer OL is formed on the second display substrate 203, and a photoresist layer 34 is formed on the organic layer OL. The organic layer OL may be formed from an organic composition that is not photo-sensitive. The photoresist layer 34 is formed from a photoresist composition that includes from about 20% to about 50% by weight of a polymer, from about 0.5% to about 1.5% by weight of a photo-acid generator, from about 0.01% to about 0.5% by weight of a photo absorber and the remainder includes an organic solvent.

A mask 50 is disposed on the photoresist layer 34, and the photoresist layer 34 is exposed to light. The mask 50 includes a light-blocking portion 52 and a light-transmitting portion 54. For example, when the width of the bar-patterns is uniform and when the distance between adjacent bar-patterns varies, the width of the light-blocking portion 52 may he uniform, and the width of the light-transmitting portion 54 can be designed to gradually increase along one direction.

After the photoresist layer 34 is exposed to light, the photoresist layer 34 is developed to form a photo pattern (not shown). The organic layer OL is patterned by using the photo pattern as an etch-stop layer to form the light path converting layer 600 including the first and second patterns N1 and N2.

Referring to FIGS. 10 and 11, the light path converting layer 600 is formed directly on the second display substrate 203. However, a light path converting sheet having a similar structure to the light path converting layer 600 may be separately manufactured and then combined with the display panel.

As described above, the photoresist composition including the photo absorber may be used for forming the light path converting layer 600 that includes stable and fine bar-patterns.

According to an example embodiment of the present invention, the photoresist composition includes a photo absorber added to a polymer and a photo-acid generator. Thus, even if light diffracts between light-blocking portions of a mask so that a photoresist layer under the light-blocking portions receives scattered light, the photo absorber may absorb the scattering light. Thus, activation of the photo-acid generator in a non-exposed portion of the photoresist layer may be prevented. Therefore, the light-exposing margin of the photoresist layer may be improved.

Furthermore, the dissolution contrast, which is the solubility difference between a light-exposed portion and a non-exposed portion of a photoresist layer formed from the photoresist composition, may be increased.

As described above, the photoresist composition according to an example embodiment of the present invention has improved characteristics. Thus, when the photoresist composition is used for forming a fine pattern, reliability and stability of the fine pattern may be improved.

The foregoing is illustrative of an example embodiment of the present invention and is not to be construed as limiting. Although a few examples of an embodiment of the present invention have been described, those skilled in the art will readily appreciate that many modifications are possible in the examplary embodiment without materially departing from the novel teachings and advantages of the present invention. Accordingly, all such modifications are intended to be included within the scope of the present invention as defined in the claims. The following claims including equivalents thereof are contemplated within the scope of the present invention.

What is claimed is:

1. A photoresist composition comprising:
from about 20% to about 50% by weight of a polymer;
from about 0.5% to about 1.5% by weight of a photo-acid generator;
from about 0.01% to about 0.5% by weight of a photo absorber; and
a remainder comprising an organic solvent.

2. The photoresist composition of claim 1, wherein the photo absorber absorbs light having a wavelength of from about 100 nm to about 450 nm.

3. The photoresist composition of claim 1, wherein the photo absorber includes at least one compound selected from the group consisting of a hydroxyphenyl benzotriazole-based compound, a hydroxyphenyl triazine-based compound, a hindered amine light stabilizer-based compound and a red shift-based compound.

4. The photoresist composition of claim 3, wherein the photo absorber includes at least one Tinuvin® compound selected from the group consisting of Tinuvin®-928, Tinuvin®-328, Tinuvin®-109, Tinuvin®-384-2, Tinuvin®-405, Tinuvin®-400, Tinuvin®-292HP, Tinuvin®-123 and Tinuvin®-477.

5. The photoresist composition of claim 1, wherein the polymer has a main chain that is alkali-soluble.

6. The photoresist composition of claim 1, wherein the polymer includes a novolac-based resin having an ethyl vinyl ether blocking an hydroxyl group of the novolac-based resin.

7. The photoresist composition of claim 1, wherein the polymer includes a styrene-based resin having tert-butylacetate blocking a monomer of polyhydroxystyrene.

8. The photoresist composition of claim 1, wherein the photo-acid generator includes at least one chemical selected from the group consisting of a diazonium salt, an ammonium salt, an iodonium salt such as diphenyliodonium triflate, a sulfonium salt such as triphenylsulfonium triflate, a phosphonium salt, an arsonium salt, an oxonium salt, a halogenated organic compound, a quinonediazide compound, a bis(sulfonyl)diazomethane compound, a sulfonic compound, an ester of organic acid compound, an amide of organic acid compound and an imide of organic acid compound.

9. The photoresist composition of claim 1, wherein the organic solvent includes at least one organic solvent selected from the group consisting of a glycol ether, an ethylene glycol alkyl ether acetate and a diethylene glycol.

10. The photoresist composition of claim 1, wherein the photoresist composition forms a photoresist layer having a light-exposed portion that is soluble in an alkali developing solution, and a non-exposed portion that is not soluble in the alkali developing solution.

11. A method of forming a fine pattern, the method comprising:
forming a thin film on a substrate;
forming a photoresist pattern by using a photoresist composition including from about 20% to about 50% by weight of a polymer, from about 0.5% to about 1.5% by weight of a photo-acid generator, from about 0.01% to about 0.5% by weight of a photo absorber and a remainder comprising an organic solvent;
patterning the thin film by using the photoresist pattern as an etch-stop layer to form a fine pattern.

12. The method of claim 11, wherein forming the photoresist pattern comprises:
coating the photoresist composition to form a photoresist layer;
exposing the photoresist layer to light and providing heat to the photoresist layer; and
developing the photoresist layer.

13. The method of claim 12, wherein exposing the photoresist layer comprises exposing to light the photoresist layer disposed on a heated plate having a temperature of from about 90° C. to about 130° C.

14. The method of claim 11, wherein the photo absorber includes at least one compound selected from the group consisting of a hydroxyphenyl benzotriazole-based compound, a hydroxyphenyl triazine-based compound, a hindered amine light stabilizer-based compound and a red shift-based compound.

15. The method of claim 11, wherein the polymer includes a novolac-based resin having an ethyl vinyl ether group blocking an hydroxyl group of the novolac-based resin.

16. The method of claim 12, wherein a light-exposed portion of the photoresist layer is removed by a developing solution.

17. The method of claim 11, wherein the substrate includes a switching element, and the fine pattern is a pixel electrode contacting the switching element and including a plurality of micro electrodes having a width of from about 1 μm to about 5 μm.

18. The method of claim 11, wherein the fine pattern includes a plurality of lattice patterns having a width of from about 1 μm to about 5 μm.

19. The method of claim 14, wherein the substrate includes a display substrate adapted for a display device.

20. The method of claim 11, wherein the fine pattern includes a plurality of patterns, and adjacent patterns being increasingly farther apart with distance from a predetermined position in one direction.
